(19) United States
(12) Patent Application Publication
(10) Pub. No.: US 2026/0247774 A1
(43) Pub. Date: Aug. 20, 2026

(54) DISPLAY DEVICE INCLUDING AN INTERMEDIATE BRIDGE PATTERN LAYER AND ELECTRONIC DEVICE COMPRISING DISPLAY DEVICE

(71) Applicant: SAMSUNG DISPLAY CO., LTD., YONGIN-SI (KR)

(72) Inventors: Seong Baik CHU, Yongin-si (KR); Tae Sik KIM, Yongin-si (KR); Young Woo PARK, Yongin-si (KR); Hyun Wook LEE, Yongin-si (KR); Taek Ju JUNG, Yongin-si (KR)

(21) Appl. No.: 19/170,126

(22) Filed: Apr. 4, 2025

(30) Foreign Application Priority Data
Jul. 17, 2024 (KR) 10-2024-0094584

(51) Int. Cl. H10H 29/49; H10H 29/41

(52) U.S. Cl. CPC H10H 29/49; H10H 29/41

(57) ABSTRACT

A display device including: a base layer; pixels each including sub-pixels; a demultiplexer; a driving circuit part; data lines connecting the demultiplexer to the sub-pixels; a data base line connecting the demultiplexer to the driving circuit part, and including first and second data base lines; a data connection line connected to the data base line, and including a first data connection line having 1-1-th and 1-2-th data connection lines, and a second data connection line having 2-1-th and 2-2-th data connection lines; a bridge layer including a first bridge layer connected to the 1-1-th and 1-2-th data connection lines, and a second bridge layer connected to the 2-1-th and 2-2-th data connection lines; and an intermediate bridge pattern layer connecting the first data base line to the first bridge layer, and overlapping the second bridge layer, and having a width greater than the first data base line.

### CROSS-REFERENCE TO RELATED APPLICATION

This application claims priority under 35 U.S.C. § 119(a) to Korean Patent Application No. 10-2024-0094584, filed in the Korean Intellectual Property Office on July 17, 2024, the disclosure of which is incorporated by reference herein in its entirety.

### TECHNICAL FIELD

Various embodiments of the present invention relate to a display device, and more particularly, to a display device including an intermediate bridge pattern layer and an electronic device comprising the display device.

### DISCUSSION OF THE RELATED ART

Recently, as information is increasingly viewed through display devices, display devices continue to be under development. Generally, display devices include pixels, and a plurality of lines that is electrically connected to the pixels and that is patterned according to a structure. It is desirable that the plurality of lines be patterned according to an intended structure.

### SUMMARY

According to an embodiment of the present invention, a display device includes a display area and a non-display area. The display device further includes: a base layer formed across the display area and the non-display area; pixels disposed on the base layer and in the display area, wherein each of the pixels includes sub-pixels; a demultiplexer disposed in the non-display area; a driving circuit part disposed adjacent to the demultiplexer and disposed in the non-display area; data lines electrically connecting the demultiplexer to the sub-pixels; a data base line electrically connecting the demultiplexer to the driving circuit part, wherein the data base line includes a first data base line and a second data base line; a data connection line electrically connecting the demultiplexer to the data base line, wherein the data connection line includes a first data connection line and a second data connection line, wherein the first data connection line is electrically connected to the first data base line and includes a 1-1-th data connection line and a 1-2-th data connection line, and the second data connection line is electrically connected to the second data base line and includes a 2-1-th data connection line and a 2-2-th data connection line; a bridge layer including a first bridge layer and a second bridge layer, wherein the first bridge layer is electrically connected to the 1-1-th data connection line and the 1-2-th data connection line, and the second bridge layer is electrically connected to the 2-1-th data connection line and the 2-2-th data connection line; and an intermediate bridge pattern layer electrically connecting the first data base line to the first bridge layer, wherein the intermediate bridge pattern layer overlaps the second bridge layer, and has a width greater than a width of the first data base line.

In an embodiment of the present invention, the intermediate bridge pattern layer includes a side surface that forms an interfacial angle with respect to a layer on which the intermediate bridge pattern layer is disposed, and wherein the interfacial angle ranges from about 30° to about 70°.

In an embodiment of the present invention, a width of the intermediate bridge pattern layer is about 6 μm or more.

In an embodiment of the present invention, a thickness of the intermediate bridge pattern layer ranges from about 3600 Å to about 4200 Å.

In an embodiment of the present invention, the intermediate bridge pattern layer includes a first conductive layer including titanium (Ti), and a second conductive layer disposed on the first conductive layer and including aluminum (Al), wherein a thickness of the first conductive layer ranges from about 200 Å to about 400 Å, and wherein a thickness of the second conductive layer ranges from about 3200 Å to about 3800 Å.

In an embodiment of the present invention, the display device further includes: a first interlayer conductive layer disposed on the base layer; a second interlayer conductive layer disposed on the first interlayer conductive layer; and a transistor conductive layer disposed on the second interlayer conductive layer, wherein the data connection line is formed from the first interlayer conductive layer, wherein the data base line and the intermediate bridge pattern layer are formed from the second interlayer conductive layer, and wherein the bridge layer is formed from the transistor conductive layer.

In an embodiment of the present invention, the pixels includes a first pixel and a second pixel adjacent to each other in a first direction, wherein the demultiplexer includes a first demux transistor and a second demux transistor, wherein the first pixel is electrically connected to the first demux transistor, and wherein the second pixel is electrically connected to the second demux transistor.

In an embodiment of the present invention, the display device further includes: a first select control line electrically connected to a gate electrode of the first demux transistor; and a second select control line electrically connected to a gate electrode of the second demux transistor, wherein each of the first select control line and the second select control line extend in the first direction.

In an embodiment of the present invention, the first demux transistor includes a plurality of first demux transistors, wherein the second demux transistor includes a plurality of second demux transistors, wherein the 1-1-th data connection line is electrically connected to one of the plurality of first demux transistors, wherein the 2-1-th data connection line is electrically connected to another of the plurality of first demux transistors, wherein the 1-2-th data connection line is electrically connected to one of the plurality of second demux transistors, and wherein the 2-2-th data connection line is electrically connected to another of the plurality of second demux transistors.

In an embodiment of the present invention, the 1-1-th data connection line, the 1-2-th data connection line, the 2-1-th data connection line, and the 2-2-th data connection line extend in a second direction that is different from the first direction.

In an embodiment of the present invention, the first bridge layer electrically connects the 1-1-th data connection line and the 1-2-th data connection line, which are spaced apart from each other in the first direction, to each other, and wherein the second bridge layer electrically connects the 2-1-th data connection line and the 2-2-th data connection line, which are spaced apart from each other in the first direction, to each other.

In an embodiment of the present invention, the second bridge layer is disposed between the first bridge layer and the first data base line such that the intermediate bridge pattern layer and the second bridge layer overlap each other.

In an embodiment of the present invention, at least a portion of the data base line extends in the second direction.

In an embodiment of the present invention, the display device further includes a bridge pattern layer electrically connecting the first data base line and the intermediate bridge pattern layer to each other, and disposed on a layer that is different from which the first data base line and the intermediate bridge pattern layer are disposed on.

In an embodiment of the present invention, the sub-pixels includes a first sub-pixel, a second sub-pixel, and a third sub-pixel, wherein the data lines include a 1-1-th data line electrically connected to the first sub-pixel of the first pixel, a 2-1-th data line electrically connected to the second sub-pixel of the first pixel, a 3-1-th data line electrically connected to the third sub-pixel of the first pixel, a 1-2-th data line electrically connected to the first sub-pixel of the second pixel, a 2-2-th data line electrically connected to the second sub-pixel of the second pixel, and a 3-2-th data line electrically connected to the third sub-pixel of the second pixel, wherein the 1-1-th data line, the 2-1-th data line, and the 3-1-th data line are respectively electrically connected to the plurality of first demux transistors, and wherein the 1-2-th data line, the 2-2-th data line, and the 3-2-th data line are respectively electrically connected to the plurality of second demux transistors.

In an embodiment of the present invention, the data base line includes a third data base line, wherein the data connection line includes a third data connection line including a 3-1-th data connection line and a 3-2-th data connection line, and electrically connected to the third data base line, and wherein the 3-1-th data connection line extends in the second direction, and overlaps the first bridge layer and the second bridge layer.

In an embodiment of the present invention, the bridge layer includes a third bridge layer electrically connected to the 3-1-th data connection line and the 3-2-th data connection line, and wherein the second bridge layer is disposed between the first bridge layer and the third bridge layer.

In an embodiment of the present invention, the intermediate bridge pattern layer is disposed across the second bridge layer and the third bridge layer, and overlaps at least a portion of the second bridge layer, and overlaps at least a portion of the third bridge layer.

In an embodiment of the present invention, the intermediate bridge pattern layer includes a first intermediate bridge pattern layer and a second intermediate bridge pattern layer, wherein the first intermediate bridge pattern layer overlaps the second bridge layer, and the second intermediate bridge pattern layer overlaps the third bridge layer, and wherein the first intermediate bridge pattern layer and the second intermediate bridge pattern layer are spaced apart from each other.

In an embodiment of the present invention, the intermediate bridge pattern layer includes a protrusion protruding in a direction between the second bridge layer and the third bridge layer.

According to an embodiment of the present invention, an electronic device includes: a display device; and a power supply configured to provide power to the display device, wherein the display device includes: a display area; a non-display area; a base layer formed across the display area and the non-display area; pixels disposed on the base layer and in the display area, wherein each of the pixels includes sub-pixels; a demultiplexer disposed in the non-display area; a driving circuit part disposed adjacent to the demultiplexer and disposed in the non-display area; data lines electrically connecting the demultiplexer to the sub-pixels; a data base line electrically connecting the demultiplexer to the driving circuit part, wherein the data base line includes a first data base line and a second data base line; a data connection line electrically connecting the demultiplexer to the data base line, wherein the data connection line includes a first data connection line and a second data connection line, wherein the first data connection line is electrically connected to the first data base line and includes a 1-1-th data connection line and a 1-2-th data connection line, and the second data connection line is electrically connected to the second data base line and includes a 2-1-th data connection line and a 2-2-th data connection line; a bridge layer including a first bridge layer and a second bridge layer, wherein the first bridge layer is electrically connected to the 1-1-th data connection line and the 1-2-th data connection line, and the second bridge layer is electrically connected to the 2-1-th data connection line and the 2-2-th data connection line; and an intermediate bridge pattern layer electrically connecting the first data base line to the first bridge layer, wherein the intermediate bridge pattern layer overlaps the second bridge layer, and has a width greater than a width of the first data base line.

In an embodiment of the present invention, the intermediate bridge pattern layer includes a side surface that forms an interfacial angle with respect to a layer on which the intermediate bridge pattern layer is disposed.

In an embodiment of the present invention, the display device further includes a bridge pattern layer electrically connecting the intermediate bridge pattern layer to the first data base line.

In an embodiment of the present invention, the 2-1-th data connection line overlaps the first bridge layer.

In an embodiment of the present invention, the data base line includes a third data base line, wherein the data connection line includes a third data connection line including a 3-1-th data connection line and a 3-2-th data connection line, and electrically connected to the third data base line, and wherein the 3-1-th data connection line overlaps the first bridge layer and the second bridge layer.

In an embodiment of the present invention, the bridge layer includes a third bridge layer electrically connected to the 3-1-th data connection line and the 3-2-th data connection line, and wherein the intermediate bridge pattern layer overlaps the third bridge layer.

### BRIEF DESCRIPTION OF THE DRAWINGS

FIG. 1 is a schematic perspective view illustrating a display device in accordance with an embodiment of the present invention.

FIG. 2 is a schematic plan view illustrating the display device in accordance with an embodiment of the present invention.

FIG. 3 is a schematic side view illustrating the display device in accordance with an embodiment of the present invention.

FIG. 4 is a schematic diagram for describing the display device in accordance with an embodiment of the present invention.

FIG. 5 is a schematic plan view illustrating a display area and a non-display area in which a driving circuit part is disposed in accordance with an embodiment of the present invention.

FIG. 6 is a schematic plan view illustrating an area where first and second demux transistors of a demultiplexer and lines electrically connected to the first and second demux transistors are disposed in accordance with an embodiment of the present invention.

FIG. 7 is a schematic sectional view illustrating the display device in accordance with an embodiment of the present invention.

FIG. 8 is a schematic sectional view illustrating a circuit layer in accordance with an embodiment of the present invention.

FIG. 9 is a schematic plan view illustrating an area between the demultiplexer and the driving circuit part in accordance with an embodiment of the present invention.

FIG. 10 is a schematic sectional view taken along line A-A’ of FIG. 9.

FIG. 11 is a schematic sectional view taken along line B-B’ of FIG. 9.

FIG. 12 is a schematic sectional view taken along line C-C’ of FIG. 9.

FIG. 13 is a schematic sectional view taken along line D-D’ of FIG. 9.

FIGS. 14 and 15 are schematic diagrams for describing a process risk, which may occur during an etching process for a conductive layer.

FIG. 16 is a schematic plan view illustrating an area between the demultiplexer and the driving circuit part in accordance with an embodiment of the present invention.

FIG. 17 is a schematic plan view illustrating an area between the demultiplexer and the driving circuit part in accordance with an embodiment of the present invention.

FIG. 18 is a block diagram of an electronic device according to an embodiment.

FIG. 19 shows schematic views of various embodiments of an electronic device.

### DETAILED DESCRIPTION OF THE EMBODIMENTS

As the present disclosure allows for various changes and numerous embodiments, example embodiments of the present invention will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element. In the present disclosure, the singular forms and/or elements are intended to include the plural forms and/or as well, unless the context clearly indicates otherwise.

Furthermore, in a case where a first part such as a layer, a film, a region, or a plate is disposed on a second part, the first part might not only be directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in a case where a first part such as a layer, a film, a region, or a plate is under a second part, the first part might not be only directly under the second part but a third part may intervene between them.

In the drawings and specification, like reference numerals and/or characters may refer to like elements, and thus, repetitive descriptions may be omitted or briefly discussed.

"About" or "approximately" as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, "about" can mean within one or more standard deviations, or within ± 30%, 20%, 10% or 5% of the stated value.

Various embodiments of the present invention relate to a display device and an electronic device comprising the display device. Hereinafter, a display device in accordance with an embodiment and an electronic device comprising the display device will be described with reference to the attached drawings.

Embodiments of the present invention pertains to a display device with increased display quality and an electronic device comprising the display device. According to embodiments of the present invention, the display device includes display and non-display areas, a demultiplexer, driving circuits, and data lines. The display device further includes an intermediate bridge pattern layer, which may provide increased electrical connectivity while reducing risks of short circuits or residual conductive structures during manufacturing. The intermediate bridge pattern layer may include specific geometric properties, such as a controlled width and an interfacial angle, to increase its performance and ensure reliable production outcomes.

The intermediate bridge pattern layer overlaps other conductive elements in a structured manner, minimizing fabrication defects and improving electrical performance. This approach significantly decreases the likelihood of unintended connections, which can cause data distortion and degrade display quality. By fine-tuning materials like titanium and aluminum in layered compositions, the device may achieve excellent structural and functional balance.

Additionally, embodiments of the present invention disclose an arrangement of sub-pixels and lines in the display area, including techniques for managing connections via demultiplexers and bridge layers. This may provide a high-resolution output and effective data transmission for each pixel. Moreover, the display device, according to embodiments of the present invention, may have increased integration of various circuit components, which may increase overall device functionality and manufacturing yield.

Embodiments of the present invention may provide solutions for precise line structuring and efficient data handling while addressing challenges such as short circuits and defect risks. Accordingly, a display device with increased performance and display quality and an electronic device comprising the display device may be provided.

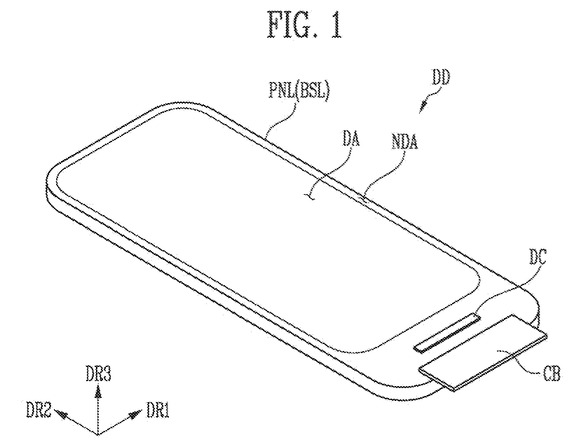

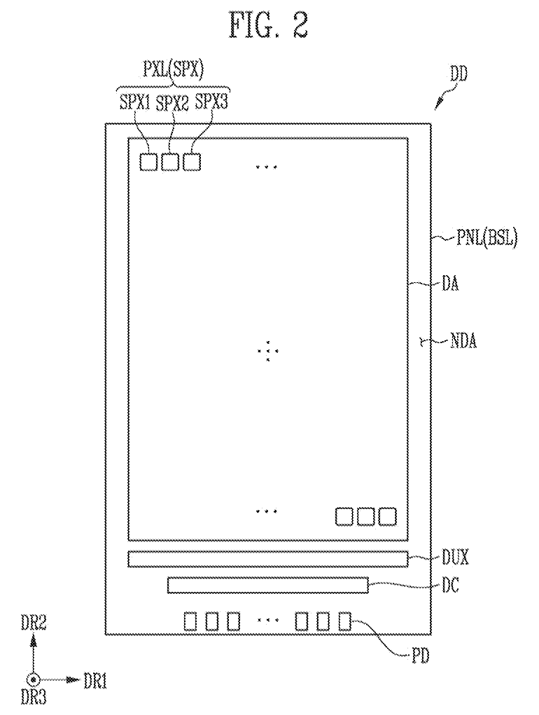

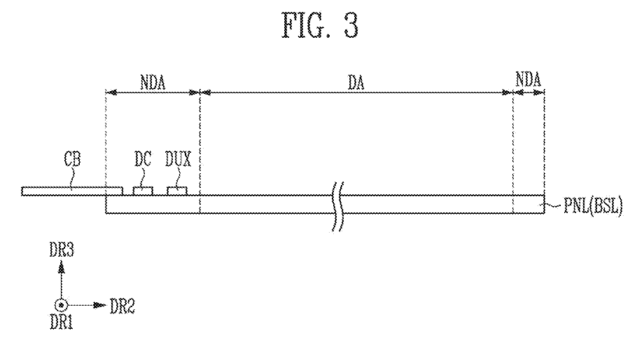

FIG. 1 is a schematic perspective view illustrating a display device DD in accordance with an embodiment of the present invention. FIG. 2 is a schematic plan view illustrating the display device DD in accordance with an embodiment of the present invention. FIG. 3 is a schematic side view illustrating the display device DD in accordance with an embodiment of the present invention.

Referring to FIGS. 1 to 3, the display device DD is configured to emit light. The display device DD may include a panel PNL, a driving circuit part DC, pads PAD, a circuit board CB, and a demultiplexer DUX. The panel PNL may include a base layer BSL therein. The display device DD may include a display area DA and a non-display area NDA.

The base layer BSL may form a base surface of the display device DD. In an embodiment of the present invention, the base layer BSL may be a bottom substrate for disposing layers that forms the display device DD. The base layer BSL may be a rigid or flexible substrate or film. For example, the base layer BSL may include glass material. In addition, the base layer BSL may include, for example, silicon material. Further, the base layer BSL may include, for example, polyimide. However, the present invention is not limited to the aforementioned example.

A plane defined in this specification may extend in a first direction DR1 and a second direction DR2, and may be defined based on a plane on which the base layer BSL is disposed. In an embodiment of the present invention, a third direction DR3 may correspond to a thickness direction of the base layer BSL. The third direction DR3 may correspond to a light output direction of the display device DD.

The display area DA may refer to an area in which pixels PXL are disposed. The non-display area NDA may refer to an area in which the pixels PXL are not disposed. The non-display area NDA may be disposed around a periphery of the display area DA. The non-display area NDA may at least partially enclose the display area DA. Lines, the driving circuit part DC, the pads PAD, and/or the circuit board CB which are electrically connected to the pixels PXL in the display area DA may be disposed in the non-display area NDA.

In accordance with an embodiment of the present invention, the pixels PXL (or the sub-pixels SPX) may be arranged in a stripe or PENTILE^{TM} arrangement structure or the like, but the present invention is not limited thereto.

In accordance with an embodiment of the present invention, each pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit which may emit various colors of light.

Each of the first sub-pixel SPX1, the second sub-pixel SPX2, and the third sub-pixel SPX3 may emit light in a single color.

For instance, the first sub-pixel SPX1 may be a red pixel configured to emit light in red (e.g., first color). The second sub-pixel SPX2 may be a green pixel configured to emit light in green (e.g., second color), and the third sub-pixel SPX3 may be a blue pixel configured to emit light in blue (e.g., third color). The red pixel may provide light in a wavelength band ranging from about 600 nm to about 750 nm. The green pixel may provide light in a wavelength band ranging from about 480 nm to about 560 nm. The blue pixel may provide light in a wavelength band ranging from about 370 nm to about 460 nm.

In accordance with an embodiment of the present invention, the number of second sub-pixels SPX2 may be greater than the number of first sub-pixels SPX1, or the number of third sub-pixels SPX3. The colors, arrangement order, types, and/or numbers of first sub-pixels SPX1, second sub-pixels SPX2, and the third sub-pixels SPX3 which form each pixel unit are not limited to a specific example.

The driving circuit part DC may be disposed in the non-display area NDA. For example, the driving circuit part DC may be disposed on a side (e.g., a lower end) of the display area DA. The driving circuit part DC may be disposed on a side of the demultiplexer DUX. The driving circuit part DC may be disposed between the demultiplexer DUX and the pads PD.

The driving circuit part DC may generate signals and voltages for driving the display panel PNL (e.g., the pixels PXL). The driving circuit part DC may include an integrated circuit, and may be disposed on the display panel PNL (e.g., the base layer BSL) in various ways.

The circuit board CB may be attached on a portion of the display panel PNL (e.g., the base layer BSL) in the non-display area NDA. The circuit boar CB may be electrically connected to the display panel PNL and the driving circuit part DC.

The circuit board CB may provide image data, a timing signal, a driving voltage, and the like to the display panel PNL and the driving circuit part DC. The circuit board CB may include, for example, a flexible printed circuit board, a chip-on-film, or the like. However, the present invention is not limited to the aforementioned example. In an embodiment of the present invention, the circuit board CB may be electrically connected to the pads PD by a conductive adhesive component such as an anisotropic conductive film.

The pads PD may be disposed in the non-display area NDA. The pads PD may be electrically connected to the driving circuit part DC. The pads PD may be electrically connected to the circuit board CB. The pads PD may serve as an interface between the display panel PNL and the circuit board CB. Therefore, image data, a timing signal, a driving voltage, etc., provided from the circuit board CB, may be provided to the driving circuit part DC through the pads PD.

The demultiplexer DUX may be disposed in the non-display area NDA. The demultiplexer DUX may be disposed between the display area DA and the driving circuit part DC. The demultiplexer DUX may extend along a side of the display area DA to cover the side of the display area DA where the driving circuit part DC is disposed.

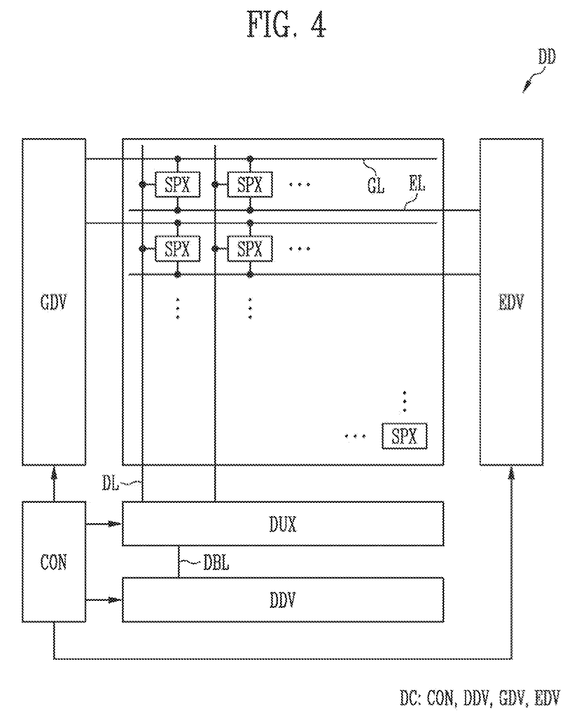

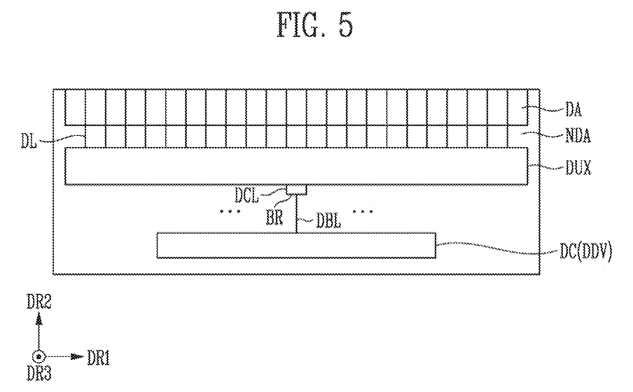

The demultiplexer DUX may be electrically connected to the sub-pixels SPX through data lines DL (refer to FIG. 4). The demultiplexer DUX may be electrically connected to the driving circuit part DC through data connection lines DCL (refer to FIG. 5) and data base lines DBL (refer to FIG. 5). In an embodiment of the present invention, the demultiplexer DUX may select one of the data lines DL and transmit a data signal, which is provided from the driving circuit part DC, to the selected data line DL.

FIG. 4 is a schematic diagram for describing the display device DD in accordance with an embodiment of the present invention.

Referring to FIG. 4, the driving circuit part DC may include a controller CON, a data driver DDV, the demultiplexer DUX, a gate driver GDV, and an emission control driver EDV. The display device 100 may include the data base lines DBL, the data lines DL, gate lines GL, and emission control lines EL.

The controller CON may be configured to convert control signals and image data, which are supplied from the circuit board CB (e.g., a processor), to match the specifications of the display device DD, and supply the required control signals, image data, and the like to the data driver DDV, the demultiplexer DUX, the gate driver GDV, and the emission control driver EDV.

Each of the sub-pixels SPX disposed in the display area DA may be electrically connected to the corresponding data line DL, the corresponding gate line GL, and the corresponding emission control line EL.

The sub-pixel SPX may be supplied with a data voltage form the data line DL in response to a gate signal received from the gate line GL. The sub-pixel SPX may emit light with a luminance corresponding to the data voltage in response to an emission control signal that is received from the emission control line EL.

The data driver DDV may receive a control signal and image data from the controller CON and generate data voltages to be supplied to the demultiplexer DUX through the data base lines DBL. The data driver DDV may supply data voltages to the demultiplexer DUX through the data base lines DBL.

The demultiplexer DUX may apply the data voltages, which are received through the data base lines DBL, to certain ones of the data lines DL and other ones of the data lines DL at different time points. The structural features of the demultiplexer DUX will be described later with reference to the drawings following FIG. 5.

The gate driver GDV may receive a control signal from the controller CON and generate a gate signal to be supplied to the gate line GL. In an embodiment of the present invention, the gate driver GDV may supply gate signals through the gate lines GL. Each gate signal may be supplied in a pulse form. The number of pulses may be set to different values depending on the embodiment. The gate driver GDV may be configured in the form of a shift register, and thus generate gate signals in such a way that a gate start signal is sequentially transmitted to a subsequent stage circuit under control of a clock signal.

The emission control driver EDV may supply emission control signals through the emission control lines EL to determine emission durations of the sub-pixels SPX. For example, each of the sub-pixels SPX may be controlled for emission by determining whether current flows through a corresponding light emitting element based on a voltage level of the emission control signal.

FIG. 5 is a schematic plan view illustrating the display area DA and the non-display area NDA in which the driving circuit part DC is disposed in accordance with an embodiment of the present invention.

Referring to FIG. 5, the display device DD may include the data connection lines DCL and bridge layers BR.

The driving circuit part DC (e.g., the data driver DDV) may be electrically connected to the demultiplexer DUX through the data base lines DBL, the bridge layers BR, and the data connection lines DCL. The demultiplexer DUX may be electrically connected to the sub-pixels SPX, which are in the display area DA, through the data lines DL.

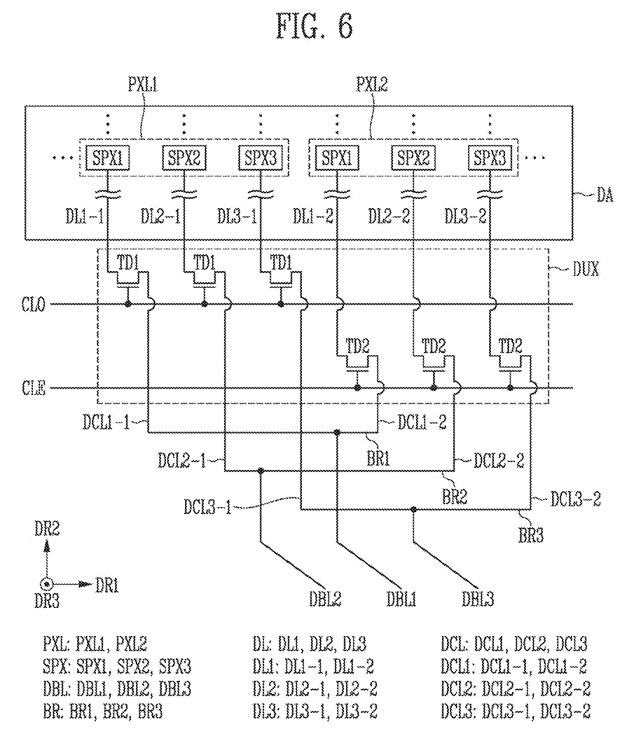

Each of the data base lines DBL may be connected to a portion of the corresponding bridge layer BR and electrically connected to the corresponding data connection lines DCL, which are branched from each other through the bridge layer BR. The branched data connection lines DCL may be connected to the respective corresponding data lines DL via first and second demux transistors TD1 and TD2 (refer to FIG. 6) of the demultiplexer DUX. Accordingly, a data signal supplied to a single data base line DBL may be selectively supplied to two or more data lines DL.

FIG. 6 is a schematic plan view illustrating an area where the first and second demux transistors TD1 and TD2 of the demultiplexer DUX and the lines electrically connected to the first and second demux transistors TD1 and TD2 are disposed in accordance with an embodiment of the present invention.

Referring to FIG. 6, there is illustrated an electrical connection structure connected to the first and second demux transistors TD1 and TD2 of the demultiplexer DUX. The display device DD may include first and second select control lines CLO and CLE.

In the present embodiment, the demultiplexer DUX may include two types of demux transistors. However, the number of demux transistors for forming the demultiplexer DUX is not limited to a specific example.

In an embodiment of the present invention, the demultiplexer DUX may include first demux transistors TD1, each of which includes a first gate electrode electrically connected to a first select control line CLO, and second demux transistors TD2, each of which includes a second gate electrode electrically connected to a second select control line CLE.

The pixels PXL may include first and second pixels PXL1 and PXL2, which are adjacent to each other, and each of which includes first to third sub-pixels SPX1 to SPX3. For example, the first and second pixels PXL1 and PXL2 may be adjacent to each other in a row direction (e.g., the first direction DR1).

In an embodiment of the present invention, the first pixel PXL1 may be electrically connected to the first demux transistors TD1, and the second pixel PXL2 may be electrically connected to the second demux transistors TD2.

The data lines DL may include a first data line DL1, a second data line DL2, and a third data line DL3.

The data lines DL may be electrically connected to the first and second demux transistors TD1 and TD2.

The first data line DL1 may include a 1-1-th data line DL1-1 and a 1-2-th data line DL1-2. The 1-1-th data line DL1-1 may be electrically connected to the corresponding first demux transistor TD1. The 1-2-th data line DL1-2 may be electrically connected to the corresponding second demux transistor TD2.

The second data line DL2 may include a 2-1-th data line DL2-1 and a 2-2-th data line DL2-2. The 2-1-th data line DL2-1 may be electrically connected to the corresponding first demux transistor TD1. The 2-2-th data line DL2-2 may be electrically connected to the corresponding second demux transistor TD2.

The third data line DL3 may include a 3-1-th data line DL3-1 and a 3-2-th data line DL3-2. The 3-1-th data line DL3-1 may be electrically connected to the corresponding first demux transistor TD1. The 3-2-th data line DL3-2 may be electrically connected to the corresponding second demux transistor TD2.

The data connection lines DCL may include a first data connection line DCL1, a second data connection line DCL2, and a third data connection line DCL3.

The data connection lines DCL may be electrically connected to the first and second demux transistors TD1 and TD2.

The first data connection line DCL1 may include a 1-1-th data connection line DCL1-1 and a 1-2-th data connection line DCL1-2. The 1-1-th data connection line DCL1-1 may be electrically connected to the corresponding first demux transistor TD1. The 1-2-th data connection line DCL1-2 may be electrically connected to the corresponding second demux transistor TD2.

The second data connection line DCL2 may include a 2-1-th data connection line DCL2-1 and a 2-2-th data connection line DCL2-2. The 2-1-th data connection line DCL2-1 may be electrically connected to the corresponding first demux transistor TD1. The 2-2-th data connection line DCL2-2 may be electrically connected to the corresponding second demux transistor TD2.

The third data connection line DCL3 may include a 3-1-th data connection line DCL3-1 and a 3-2-th data connection line DCL3-2. The 3-1-th data connection line DCL3-1 may be electrically connected to the corresponding first demux transistor TD1. The 3-2-th data connection line DCL3-2 may be electrically connected to the corresponding second demux transistor TD2.

The 1-1-th data line DL1-1 may be electrically connected to the first sub-pixel SPX1 of the first pixel PXL1. The 1-2-th data line DL1-2 may be electrically connected to the first sub-pixel SPX1 of the second pixel PXL2.

The 2-1-th data line DL2-1 may be electrically connected to the second sub-pixel SPX2 of the first pixel PXL1. The 2-2-th data line DL2-2 may be electrically connected to the second sub-pixel SPX2 of the second pixel PXL2.

The 3-1-th data line DL3-1 may be electrically connected to the third sub-pixel SPX3 of the first pixel PXL1. The 3-2-th data line DL3-2 may be electrically connected to the third sub-pixel SPX3 of the second pixel PXL2.

A first electrode of one (e.g., a first first demux transistor TD1) of the first demux transistors TD1 may be electrically connected to the 1-1-th data connection line DCL1-1, and a second electrode of the first demux transistor TD1 (e.g., the first first demux transistor TD1) may be electrically connected to the 1-1-th data line DL1-1.

A first electrode of another (e.g., a second first demux transistor TD1) of the first demux transistors TD1 may be electrically connected to the 2-1-th data connection line DCL2-1, and a second electrode of the first demux transistor TD1 (e.g., the second first demux transistor TD1) may be electrically connected to the 2-1-th data line DL2-1.

A first electrode of a remaining one of the first demux transistors TD1 (e.g., a third first demux transistor TD1) may be electrically connected to the 3-1-th data connection line DCL3-1, and a second electrode of the first demux transistor TD1 (e.g., the third first demux transistor TD1) may be electrically connected to the 3-1-th data line DL3-1.

A first electrode of one (e.g., a first second demux transistor TD2) of the second demux transistors TD2 may be electrically connected to the 1-2-th data connection line DCL1-2, and a second electrode of the second demux transistor TD2 (e.g., the first second demux transistor TD2) may be electrically connected to the 1-2-th data line DL1-2.

A first electrode of another (e.g., a second second demux transistor TD2) of the second demux transistors TD2 may be electrically connected to the 2-2-th data connection line DCL2-2, and a second electrode of the second demux transistor TD2 (e.g., the second second demux transistor TD2) may be electrically connected to the 2-2-th data line DL2-2.

A first electrode of a remaining one (e.g., a third second demux transistor TD2) of the second demux transistors TD2 may be electrically connected to the 3-2-th data connection line DCL3-2, and a second electrode of the second demux transistor TD2 (e.g., the third second demux transistor TD2) may be electrically connected to the 3-2-th data line DL3-2.

Each of the data base lines DBL may be electrically connected to the corresponding data connection lines DCL through the corresponding bridge layer BR.

The data base lines DBL may include a first data base line DBL1, a second data base line DBL2, and a third data base line DBL3. The bridge layers BR may include a first bridge layer BR1, a second bridge layer BR2, and a third bridge layer BR3.

The first data base line DBL1 may extend in the second direction DR2, and may be electrically connected to the 1-1-th data connection line DCL1-1 and the 1-2-th data connection line DCL1-2 through the first bridge layer BR1. For example, the first bridge layer BR1 may extend in the first direction DR1, and the 1-1-th data connection line DCL1-1 and the 1-2-th data connection line DCL1-2 may extend in the second direction DR2. The 1-1-th data connection line DCL1-1 and the 1-2-th data connection line DCL1-2 may be electrically connected to the first bridge layer BR1 at respective certain positions.

The second data base line DBL2 may extend in the second direction DR2, and may be electrically connected to the 2-1-th data connection line DCL2-1 and the 2-2-th data connection line DCL2-2 through the second bridge layer BR2. For example, the second bridge layer BR2 may extend in the first direction DR1, and the 2-1-th data connection line DCL2-1 and the 2-2-th data connection line DCL2-2 may extend in the second direction DR2. The 2-1-th data connection line DCL2-1 and the 2-2-th data connection line DCL2-2 may be electrically connected to the second bridge layer BR2 at respective certain positions.

The third data base line DBL3 may extend in the second direction DR2, and may be electrically connected to the 3-1-th data connection line DCL3-1 and the 3-2-th data connection line DCL3-2 through the third bridge layer BR3. For example, the third bridge layer BR3 may extend in the first direction DR1, and the 3-1-th data connection line DCL3-1 and the 3-2-th data connection line DCL3-2 may extend in the second direction DR2. The 3-1-th data connection line DCL3-1 and the 3-2-th data connection line DCL3-2 may be electrically connected to the third bridge layer BR3 at respective certain positions.

Accordingly, a data voltage supplied through any one of the data base lines DBL may be supplied to any one of the sub-pixels SPX of the first pixel PXL1 via the corresponding first demux transistor TD1, or may be supplied to any one of the sub-pixels SPX of the second pixel PXL2 via the corresponding second demux transistor TD2.

The first select control line CLO may extend in the first direction DR1, and may be electrically connected to the first demux transistors TD1 at multiple nodes, respectively.

The first select control line CLO may supply a first select control signal to the first gate electrode of each first demux transistor TD1. In the case where the first select control signal is supplied to the first gate electrode of the first demux transistor TD1, the first demux transistor TD1 may be turned on, while the second demux transistor TD2 may remain in a turn-off state. Hence, a data signal supplied through any one of the data base lines DBL may be supplied to a corresponding one of the sub-pixels SPX of the first pixel PXL1 through the corresponding first demux transistor TD1 and the corresponding data line DL in response to the first select control signal.

The second select control line CLE may extend in the first direction DR1, and may be electrically connected to the second demux transistors TD2 at multiple nodes, respectively.

The second select control line CLE may supply a second select control signal to the second gate electrode of each second demux transistor TD2. In the case where the second select control signal is supplied to the second gate electrode of the second demux transistor TD2, the second demux transistor TD2 may be turned on, while the first demux transistor TD1 may remain in a turn-off state. Hence, a data signal supplied through any one of the data base lines DBL may be supplied to a corresponding one of the sub-pixels SPX of the second pixel PXL2 through the corresponding second demux transistor TD2 and the corresponding data line DL in response to the second select control signal.

In an embodiment of the present invention, the first demux transistors TD1 may be turned on, and the second demux transistors TD2 may be turned off. In this case, a data signal supplied, which is supplied to the first data base line DBL1, may be supplied to the first sub-pixel SPX1 of the first pixel PXL1 through the first bridge layer BR1, the 1-1-th data connection line DCL1-1, the corresponding first demux transistor TD1, and the 1-1-th data line DL1-1.

In an embodiment of the present invention, the first demux transistors TD1 may be turned off, and the second demux transistors TD2 may be turned on. In this case, a data signal, which is supplied to the first data base line DBL1, may be supplied to the first sub-pixel SPX1 of the second pixel PXL2 through the first bridge layer BR1, the 1-2-th data connection line DCL1-2, the corresponding second demux transistor TD2, and the 1-2-th data line DL1-2.

In an embodiment of the present invention, the first demux transistors TD1 may be turned on, and the second demux transistors TD2 may be turned off. In this case, a data signal, which is supplied to the second data base line DBL2, may be supplied to the second sub-pixel SPX2 of the first pixel PXL1 through the second bridge layer BR2, the 2-1-th data connection line DCL2-1, the corresponding first demux transistor TD1, and the 2-1-th data line DL2-1.

In an embodiment of the present invention, the first demux transistors TD1 may be turned off, and the second demux transistors TD2 may be turned on. In this case, a data signal, which is supplied to the second data base line DBL2, may be supplied to the second sub-pixel SPX2 of the second pixel PXL2 through the second bridge layer BR2, the 2-2-th data connection line DCL2-2, the corresponding second demux transistor TD2, and the 2-2-th data line DL2-2.

In an embodiment of the present invention, the first demux transistors TD1 may be turned on, and the second demux transistors TD2 may be turned off. In this case, a data signal, which is supplied to the third data base line DBL3, may be supplied to the third sub-pixel SPX3 of the first pixel PXL1 through the third bridge layer BR3, the 3-1-th data connection line DCL3-1, the corresponding first demux transistor TD1, and the 3-1-th data line DL3-1.

In an embodiment of the present invention, the first demux transistors TD1 may be turned off, and the second demux transistors TD2 may be turned on. In this case, a data signal, which is supplied to the third data base line DBL3, may be supplied to the third sub-pixel SPX3 of the second pixel PXL2 through the third bridge layer BR3, the 3-2-th data connection line DCL3-2, the corresponding second demux transistor TD2, and the 3-2-th data line DL3-2.

In accordance with an embodiment of the present invention, the operation of the sub-pixels SPX may be controlled by the demultiplexer DUX, thereby increasing the integration of the lines and the degree of freedom in design, and increasing the transmission speed of data signals.

In an embodiment of the present invention, the bridge layer BR may extend in the first direction DR1, and may include a plurality of bridge layers BR. At least a portion of the data base line DBL may extend in the second direction DR2, and may include a plurality of data base lines DBL. In this case, at least some portions of the data base lines DBL may intersect with the bridge layers BR, in a plan view.

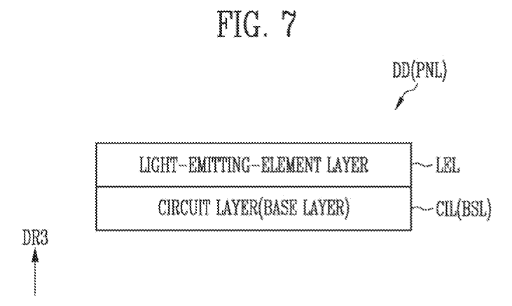

Hereinafter, planar and sectional structures of the display device DD will be described in more detail with reference to FIGS. 7 to 15.

FIG. 7 is a schematic sectional view illustrating the display device DD in accordance with an embodiment of the present invention.

Referring to FIG. 7, the display device DD (or the display panel PNL) may include a circuit layer CIL and a light-emitting-element layer LEL.

The circuit layer CIL may include a base layer BSL. The circuit layer CIL may include a layer including a pixel circuit. The circuit layer CIL may be a layer including circuits (e.g., the first and second demux transistors TD1 and TD2) that are provided to form the demultiplexer.

The light-emitting-element layer LEL may be disposed on the circuit layer CIL. The light-emitting-element layer LEL may include a light emitting element LD for forming the pixel PXL. The light emitting element may include an organic light emitting diode or a light emitting diode including inorganic material. However, the present invention is not limited to the aforementioned example.

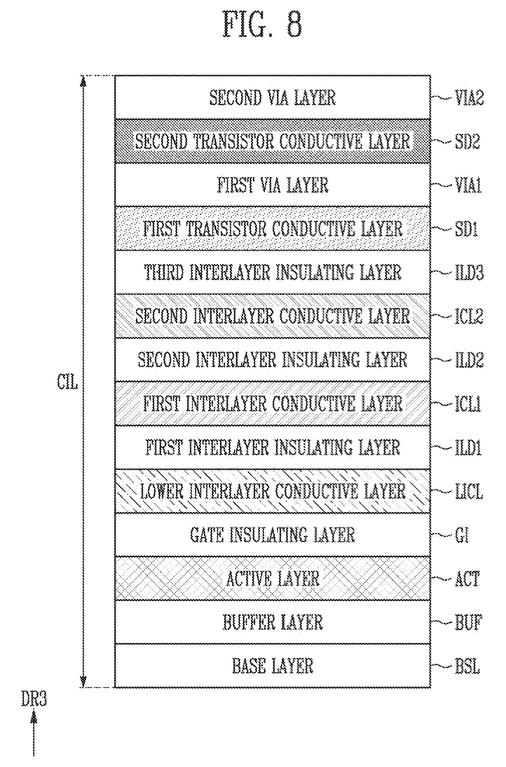

Referring to FIG. 8, a stacked structure defined in the circuit layer CIL will be described. FIG. 8 is a schematic sectional view illustrating the circuit layer CIL in accordance with an embodiment of the present invention. In the drawings following FIG. 8, layers identical to the layers that are described with reference to FIG. 8 (e.g., layers patterned through a same process) may be represented with a same hatching.

Referring to FIG. 8, the circuit layer CIL may include conductive layers, insulating layers, and the like that are disposed on the base layer BSL. For example, the circuit layer CIL may have a structure formed by stacking a base layer BSL, a buffer layer BUF, an active layer ACT, a gate insulating layer GI, a lower interlayer conductive layer LICL, a first interlayer insulating layer ILD1, a first interlayer conductive layer ICL1, a second interlayer insulating layer ILD2, a second interlayer conductive layer ICL2, a third interlayer insulating layer ILD3, a first transistor conductive layer SD1, a first via layer VIA1, a second transistor conductive layer SD2, and a second via layer VIA2, each of which having at least a portion that is patterned. The stacked structure may form the pixel circuit and the first and second demux transistors TD1 and TD2.

The buffer layer BFL may be disposed on the base layer BSL. The buffer layer BFL may prevent diffusion of impurities or penetration of water into the active layer ACT.

The active layer ACT may be disposed on the buffer layer BFL. The active layer ACT may include a semiconductor. For example, the active layer ACT may include at least one of polysilicon, low temperature polycrystalline silicon (LTPS), amorphous silicon, and/or an oxide semiconductor.

The lower interlayer conductive layer LICL, the first interlayer conductive layer ICL1, the second interlayer conductive layer ICL2, the first transistor conductive layer SD1, and the second transistor conductive layer SD2 may include conductive material, and each may have a single-layer or multilayer structure. In an embodiment of the present invention, the first transistor conductive layer SD1 may be a layer in which source/drain electrode layers of transistors included in the circuit layer CIL are formed.

The gate insulating layer GI, the first interlayer insulating layer ILD1, the second interlayer insulating layer ILD2, the third interlayer insulating layer ILD3, the first via layer VIA1, and the second via layer VIA2 may be disposed between the conductive layers (e.g., LICL, ICL1, ICL2, SD1, and SD2) included in the circuit layer CIL, and may include various insulating materials such as inorganic material and/or organic material. At least some of the conductive layers may be electrically connected to each other through a contact member CNP passing through at least one of the insulating layers.

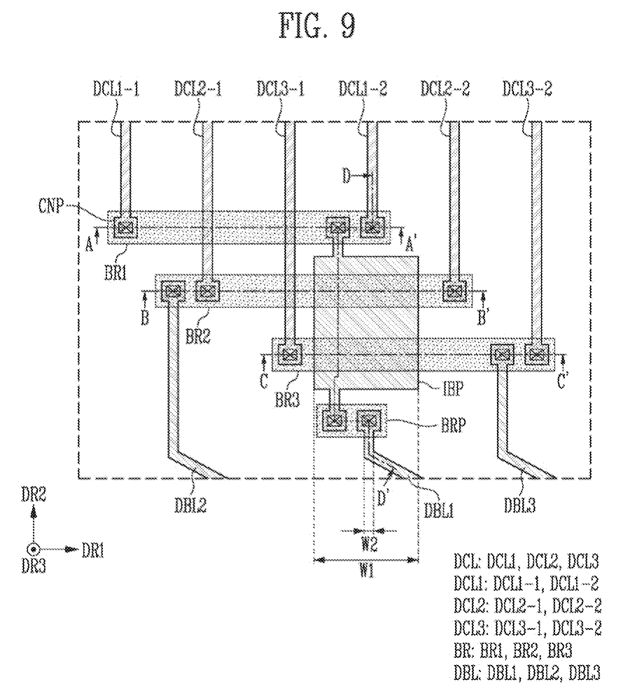

The display device DD including the demultiplexer DUX and lines electrically connected thereto in accordance with an embodiment of the present invention will be described with reference to FIGS. 9 to 15.

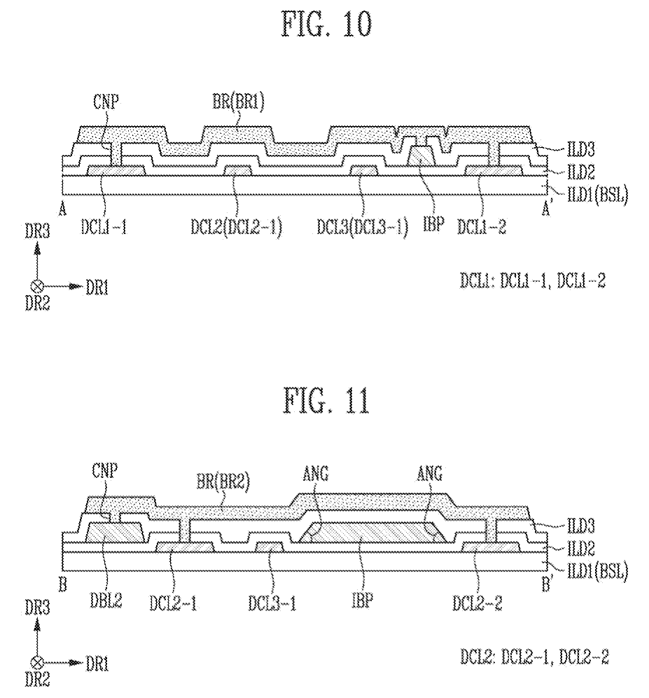

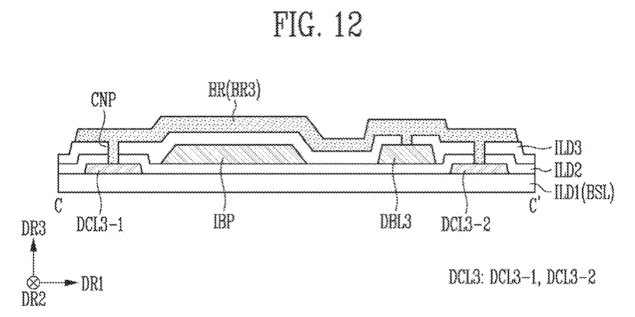

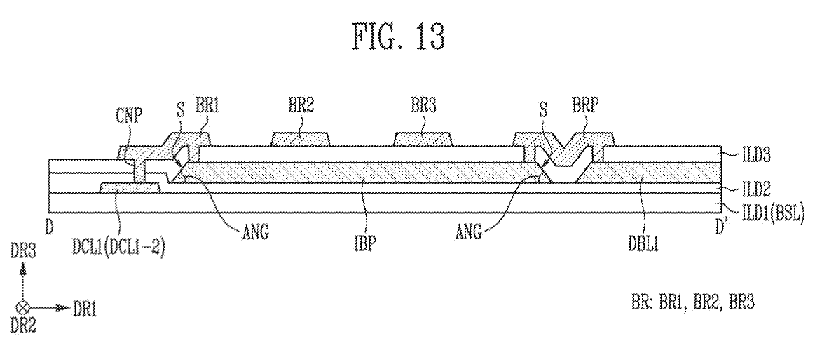

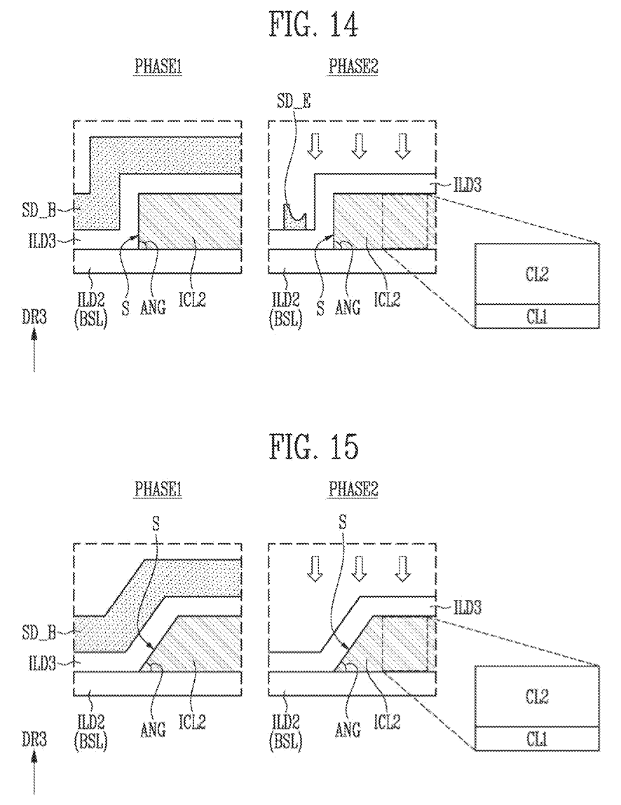

FIG. 9 is a schematic plan view illustrating an area between the demultiplexer DUX and the driving circuit part in accordance with an embodiment of present invention. FIG. 10 is a schematic sectional view taken along line A-A’ of FIG. 9. FIG. 11 is a schematic sectional view taken along line B-B’ of FIG. 9. FIG. 12 is a schematic sectional view taken along line C-C’ of FIG. 9. FIG. 13 is a schematic sectional view taken along line D-D’ of FIG. 9. FIGS. 14 and 15 are schematic diagrams for describing a process risk, which may occur during an etching process for a conductive layer.

Referring to FIGS. 9 to 13, the first interlayer conductive layer ICL1, the second interlayer conductive layer ICL2, and the first transistor conductive layer SD1 may each be patterned, thereby forming lines that are electrically connected to the demultiplexer DUX.

In an embodiment of the present invention, the 1-1-th data connection line DCL1-1, the 2-1-th data connection line DCL2-1, the 3-1-th data connection line DCL3-1, the 1-2-th data connection line DCL1-2, the 2-2-th data connection line DCL2-2, and the 3-2-th data connection line DCL3-2 may be sequentially disposed in the first direction DR1.

The 1-1-th data connection line DCL1-1 and the 1-2-th data connection line DCL1-2 may be formed from patterning the first interlayer conductive layer ICL1, and may each extend in the second direction DR2.

The 1-1-th data connection line DCL1-1 may be electrically connected to a first portion of the first bridge layer BR1 through a contact member CNP that passes through the second and third interlayer insulating layers ILD2 and ILD3.

The 1-2-th data connection line DCL1-2 may be electrically connected to a second portion of the first bridge layer BR1 through a contact member CNP that passes through the second and third interlayer insulating layers ILD2 and ILD3.

The first bridge layer BR1 may be formed from the first transistor conductive layer SD1, and may extend in the first direction DR1. Since the first bridge layer BR1 extends in the first direction DR1, the first bridge layer BR1 may overlap the 2-1-th data connection line DCL2-1 and the 3-1-th data connection line DCL3-1, in a plan view. The first bridge layer BR1 may electrically connect the 1-1-th data connection line DCL1-1 and the 1-2-th data connection line DCL1-2, which are spaced apart from each other in the first direction DR1, to each other.

The 2-1-th data connection line DCL2-1 and the 2-2-th data connection line DCL2-2 may be formed from patterning the first interlayer conductive layer ICL1, and may each extend in the second direction DR2.

The 2-1-th data connection line DCL2-1 may be electrically connected to a first portion of the second bridge layer BR2 through a contact member CNP, that passes through the second and third interlayer insulating layers ILD2 and ILD3.

The 2-2-th data connection line DCL2-2 may be electrically connected to a second portion of the second bridge layer BR2 through a contact member CNP, that passes through the second and third interlayer insulating layers ILD2 and ILD3.

The second bridge layer BR2 may be formed from the first transistor conductive layer SD1, and may extend in the first direction DR1. Since the second bridge layer BR2 extends in the first direction DR1, the second bridge layer BR2 may overlap the 3-1-th data connection line DCL3-1 and an intermediate bridge pattern layer IBP, in a plan view. The second bridge layer BR2 may electrically connect the 2-1-th data connection line DCL2-1 and the 2-2-th data connection line DCL2-2, which are spaced apart from each other in the first direction DR1, to each other. The second bridge layer BR2 may be disposed between the first bridge layer BR1 and the first data base line DBL1.

The 3-1-th data connection line DCL3-1 and the 3-2-th data connection line DCL3-2 may be formed from patterning the first interlayer conductive layer ICL1, and may each extend in the second direction DR2.

The 3-1-th data connection line DCL3-1 may be electrically connected to a first portion of the third bridge layer BR3 through a contact member CNP, that passes through the second and third interlayer insulating layers ILD2 and ILD3.

The 3-2-th data connection line DCL3-2 may be electrically connected to a second portion of the third bridge layer BR3 through a contact member CNP, that passes through the second and third interlayer insulating layers ILD2 and ILD3.

The third bridge layer BR3 may be formed from the first transistor conductive layer SD1, and may extend in the first direction DR1. Since the third bridge layer BR3 extends in the first direction DR1, the third bridge layer BR3 may overlap the intermediate bridge pattern layer IBP, in a plan view. The third bridge layer BR3 may electrically connect the 3-1-th data connection line DCL3-1 and the 3-2-th data connection line DCL3-2, which are spaced apart from each other in the first direction DR1, to each other. The third bridge layer BR3 may be disposed between the first bridge layer BR1 and the first data base line DBL1, in a plan view. In addition, the third bridge layer BR3 may be disposed between the second bridge layer BR2 and the first data base line DBL1, in a plan view.

The first bridge layer BR1 may be more adjacent to the display area DA than the second and third bridge layers BR2 and BR3. The second bridge layer BR2 may be more adjacent to the display area DA than the third bridge layer BR3. For example, the second bridge layer BR2 may be disposed between the first bridge layer BR1 and the third bridge layer BR3, in a plan view

The first data connection line DCL1 may extend to the first bridge layer BR1 in the second direction DR2. The second data connection line DCL2 may extend to the second bridge layer BR2 in the second direction DR2. The third data connection line DCL3 may extend to the third bridge layer BR3 in the second direction DR2.

The second data connection line DCL2 may extend longer than the first data connection line DCL1. Accordingly, at least a portion of the second data connection DCL2 may overlap the first bridge layer BR1 in a plan view. In addition, as an example, the at least a portion of the second data connection DCL2 may vertically overlap the first bridge layer BR1.

The third data connection line DCL3 may extend longer than each of the first and second data connection lines DCL1 and DCL2. Accordingly, at least a portion of the third data connection DCL3 may overlap each of the first and second bridge layers BR1 and BR2 in a plan view. In addition, as an example, the at least a portion of the third data connection DCL3 may vertically overlap each of the first bridge layer BR1 and the second bridge layer BR2.

In an embodiment of the present invention, the display device DD may include the intermediate bridge pattern layer IBP that electrically connects the first bridge layer BR1 and the first data base line BDL1 to each other. The display device DD may further include a bridge pattern layer BRP.

A first portion of the intermediate bridge pattern layer IBP may be electrically connected to the first bridge layer BR1 through a contact member CNP that passes through the third interlayer insulating layer ILD3.

A second portion of the intermediate bridge pattern layer IBP may be electrically connected to the bridge pattern layer BRP through a contact member CNP that passes through the third interlayer insulating layer ILD3.

The intermediate bridge pattern layer IBP may be formed from the second intermediate conductive layer ICL2. The intermediate bridge pattern layer IBP may overlap each of the second bridge layer BR2 and the third bridge layer BR3 in a plan view. For example, the intermediate bridge pattern layer IBP may vertically overlap each of the second bridge layer BR2 and the third bridge layer BR3.

The intermediate bridge pattern layer IBP may extend in the second direction DR2 between the first bridge layer BR1 and the first data bridge line DBL1. At least a portion of the intermediate bridge pattern layer IBP may have a relatively expanded shape. For example, the intermediate bridge pattern IBP may have a polygonal shape or a rounded shape.

For example, at least a portion of the intermediate bridge pattern layer IBP may extend in the first direction DR1, and at least another portion of the intermediate bridge pattern layer IBP may extend in the second direction DR2. The intermediate bridge pattern layer IBP may form a certain surface area.

The intermediate bridge pattern layer IBP may be disposed across the second bridge layer BR2 and the third bridge layer BR3. In addition, the intermediate bridge pattern layer IBP may overlap at least a portion of the second bridge layer BR2 in a longitudinal direction of the second bridge layer BR2. The intermediate bridge pattern layer IBP may overlap at least a portion of the third bridge layer BR3 in a longitudinal direction of the third bridge layer BR3.

The intermediate bridge pattern layer IBP may have a larger width than the first data base line DBL1. The intermediate bridge pattern layer IBP may have a larger width than each of the second and third data base lines DBL2 and DBL3.

For example, the intermediate bridge pattern layer IBP may have a first width W1 in the first direction DR1. The first data base line DBL1 may have a second width W2. The first width W1 may be greater than the second width W2.

The intermediate bridge pattern layer IBP may overlap substantially large areas of each of the second and third bridge layers BR2 and BR3, in a plan view.

The intermediate bridge pattern layer IBP may be formed from the second intermediate conductive layer ICL2. The second and third bridge layers BR2 and BR3, which may be formed from the first transistor conductive layer SD1, may be disposed on the intermediate bridge pattern layer IBP. For example, the second and third bridge layers BR2 and BR3 may be disposed above the intermediate bridge pattern layer IBP.

In an embodiment of the present invention, the intermediate bridge pattern layer IBP may have a shape extending in a planar direction to cover a relatively large area, and a risk in a line structure, which may occur due to the overlap between the second interlayer conductive layer ICL2 and the first transistor conductive layer SD1 in a plan view, may be reduced. Related description will be further provided with reference to FIGS. 14 and 15.

In FIGS. 14 and 15, a first phase PHASE1 represents a process step at which after the second intermediate conductive layer ICL2 is patterned on the second interlayer insulating layer ILD2, the third interlayer insulating layer ILD3 covering the second interlayer conductive layer ICL2 is formed, and a base conductive portion SD_B for forming the first transistor conductive layer SD1 is formed. In FIGS. 14 and 15, a second phase PHASE2 refers to a process step following the first phase PHASE1, and represents a process step after the base conductive portion SD_B is etched.

The second interlayer conductive layer ICL2 may have a relatively large thickness. For example, the second interlayer conductive layer ICL2 may have a thickness that is greater than each of a thickness of the lower interlayer conductive layer LICL and a thickness of the first interlayer conductive layer ICL1. For example, the second interlayer conductive layer ICL2 may have a thickness ranging from about 3600 Å to about 4200 Å. For example, the first interlayer conductive layer ICL1 may have a thickness ranging from about 2800 Å to about 3200 Å. For example, the lower interlayer conductive layer LICL may have a thickness ranging from about 2800 Å to about 3200 Å.

In this case, the second interlayer conductive layer ICL2 may be disposed on the second interlayer insulating layer ILD2, thus forming a step difference on an end thereof.

A side surface S of the second interlayer conductive layer ICL2 may form an interfacial angle ANG with respect to the plane on which the base layer BSL is disposed (or a surface on which the second interlayer insulating layer ILD2 is disposed).

Referring to FIG. 14, in the case where the side surface S of the second interlayer conductive layer ICL2 may form a relatively large slope such that the interfacial angle ANG is formed with a relatively large value, at least a portion of the base conductive portion SD_B may remain unetched in an area that is adjacent to the side surface S after an etching process for the base conductive portion SD_B is carried out, thus resulting in a residual conductive portion SD_E.

Referring to FIG. 15, in the case where the side surface S of the second interlayer conductive layer ICL2 may form a relatively gentle slope such that the interfacial angle ANG is formed with a relatively small value, the risk of at least a portion of the base conductive portion SD_B remaining unetched in an area that is adjacent to the side surface S after the etching process for the base conductive portion SD_B is carried out may be reduced, thus also reducing the risk of the residual conductive portion SD_E remaining.

Experimentally, in the case where the side surface S of the second interlayer conductive layer ICL2 has a relatively steep tapered surface, resulting in formation of the residual conductive portion SD_E that is adjacent to the second interlayer conductive layer ICL2, there may be a risk of short circuits between conductive structures that are formed by the first transistor conductive layers SD1, which are patterned on the third interlayer insulating layer ILD3. For instance, in the case where the residual conductive portion SD_E or the like is formed around the second and third bridge layers BR2 and BR3 that are formed from the first transistor conductive layers SD1, there may be a risk of short circuits between the second and third bridge layers BR2 and BR3. If a short-circuit issue occurs between the second and third bridge layers BR2 and BR3, which are supplied with different data signals, there is a possibility that the data signals may be distorted, which may lead to degradation in display quality.

Compared to this, in the case where the side surface S of the second interlayer conductive layer ICL2 forms a relatively gentle tapered surface, the risk of short circuits or the like between the conductive structures that are formed from the first transistor conductive layers SD1, which are patterned on the third interlayer insulating layer ILD3, may be reduced. For instance, in an embodiment of the present invention, the risk of formation of the residual conductive portion SD_E or the like around the second and third bridge layers BR2 and BR3, which are formed from the first transistor conductive layers SD1, may be reduced. As a result, the risk of short circuits between the second and third bridge layers BR2 and BR3 may also be reduced. Furthermore, as the risk of short circuits is reduced, the defect rate in fabricating the display device DD may decrease, leading to an increase in process yield.

Referring again to FIGS. 9 to 13, the intermediate bridge pattern layer IBP may be patterned to have a relatively large width, and the side surface S of the intermediate bridge pattern layer IBP may have a gentle slope.

For example, the interfacial angle ANG formed by the side surface S of the intermediate bridge pattern layer IBP may be about 70° or less. The interfacial angle ANG may be with respect to the side surface S and a direction of the plane on which the base layer BSL is disposed. The interfacial angle ANG may be with respect to the side surface S and the base on which the intermediate bridge pattern layer IBP is disposed. For example, the interfacial angle ANG formed by the side surface S of the intermediate bridge pattern layer IBP may range from about 30° to about 70°. Furthermore, for the interfacial angle ANG to have the numerical range described above, the first width W1 of the intermediate bridge pattern layer IBP may be about 6 μm or more. In an embodiment of the present invention, the first width W1 of the intermediate bridge pattern layer IBP may range from about 6 μm to about 15 μm. In accordance with an embodiment of the present invention, in the case where the intermediate bridge pattern layer IBP is about 6 μm or more, a side interfacial angle of a photoresist layer used to form the intermediate bridge pattern layer IBP may be formed to be relatively gentle, thereby reducing the interfacial angle ANG of the side surface S of the intermediate bridge pattern layer IBP.

For example, the intermediate bridge pattern layer IBP may have a thickness ranging from about 3600 Å to about 4200 Å. For example, the intermediate bridge pattern layer IBP may include a first conductive layer CL1 including titanium (Ti), and a second conductive layer CL2 that is disposed on the first conductive layer CL1 and includes aluminum (Al). For example, the first conductive layer CL1 may have a thickness ranging from about 200 Å to about 400 Å, while the second conductive layer CL2 may have a thickness ranging from about 3200 Å to about 3800 Å. In an embodiment of the present invention, the thickness of the first conductive layer CL1 may be approximately 300 Å, while the thickness of the second conductive layer CL2 may be approximately 3500 Å.

In the case where the first width W1 and the interfacial angle ANG of the intermediate bridge pattern layer IBP satisfy the above-mentioned numerical range, as described above (i.e., similar to the second phase PAHSE2 of FIG. 15), unintended residual conductive portion SD_E might not be formed around the second interlayer conductive layer ICL2 that forms the intermediate bridge pattern layer IBP. As a result, the risk of data signal distortion, which may lead to degradation in display quality, may be reduced, thereby enabling the provision of a display device DD with increased display quality. In addition, since lines may be formed in a relatively small area, the resolution characteristics of the sub-pixels SPX may be improved, thereby resulting in a display device DD with high-resolution characteristics.

The bridge pattern layer BRP may be electrically connected to the intermediate bridge pattern layer IBP through a contact member CNP that passes through the third interlayer insulating layer ILD3. The bridge pattern layer BRP may be disposed in a layer that is different from the intermediate bridge pattern layer IBP and the first data base line DBL1. The bridge pattern layer BRP may be electrically connected to the first data base line DBL1 through a contact member CNP that passes through the third interlayer insulating layer ILD3. Accordingly, the first data base line DBL1 may be electrically connected to the 1-1-th data connection line DCL1-1 and the 1-2-th data connection line DCL1-2 through the bridge pattern layer BRP, the intermediate bridge pattern layer IBP, and the first bridge layer BR1.

The second bridge layer BR2 may be electrically connected to the second data base line DBL2 through a contact member CNP that passes through the third interlayer insulating layer ILD3. Accordingly, the second data base line DBL2 may be electrically connected to the 2-1-th data connection line DCL2-1 and the 2-2-th data connection line DCL2-2 through the second bridge layer BR2.

The third bridge layer BR3 may be electrically connected to the third data base line DBL3 through a contact member CNP that passes through the third interlayer insulating layer ILD3. Accordingly, the third data base line DBL3 may be electrically connected to the 3-1-th data connection line DCL3-1 and the 3-2-th data connection line DCL3-2 through the third bridge layer BR3.

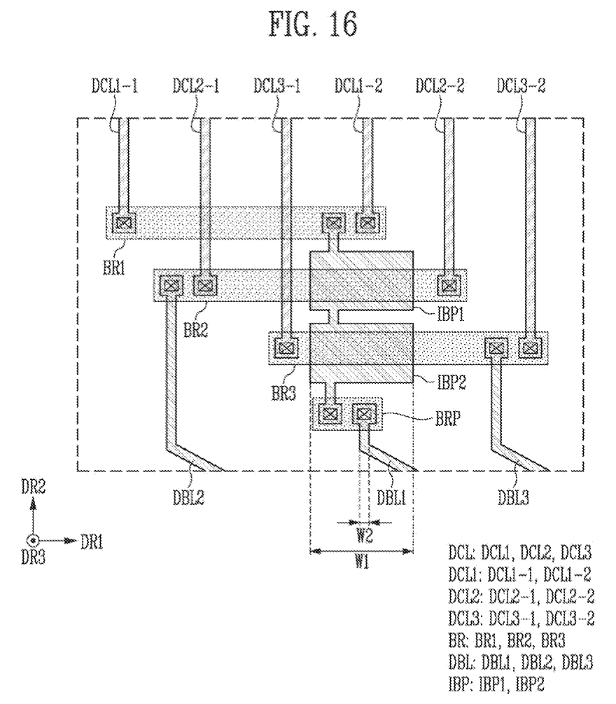

The display device DD including the demultiplexer DUX and lines electrically connected thereto in accordance with an embodiment of the present invention will be described with reference to FIGS. 16 to 15.

FIG. 16 is a schematic plan view illustrating an area between the demultiplexer DUX and the driving circuit part in accordance with an embodiment of the present invention.

The display device DD in accordance with the present embodiment is different from the display device DD in accordance with the aforementioned embodiment in that the intermediate bridge pattern layer IBP includes first and second intermediate bridge pattern layers IBP1 and IBP2 that are spaced apart from each other.

The first and second intermediate bridge patterns IBP1 and IBP2 may be spaced apart from each other in the second direction DR2, and may be disposed to correspond to the second and third bridge layers BR2 and BR3, respectively.

The first intermediate bridge pattern layer IBP1 may overlap the second bridge layer BR2 in a plan view. In addition, as an example, the first intermediate bridge pattern layer IBP1 may vertically overlap the second bridge layer BR2. The first intermediate bridge pattern layer IBP1 may be disposed between the first bridge layer BR1 and the third bridge layer BR3. The first intermediate bridge pattern layer IBP1 may be disposed between the 3-1-th data connection line DCL3-1 and the 2-2-th data connection line DCL2-2.

The second intermediate bridge pattern layer IBP2 may overlap the third bridge layer BR3 in a plan view. In addition, as an example, the second intermediate bridge pattern layer IBP2 may vertically overlap the third bridge layer BR3. The second intermediate bridge pattern layer IBP2 may be disposed between the second bridge layer BR2 and the bridge pattern layer BRP. The second intermediate bridge pattern layer IBP2 may be disposed between the 3-1-th data connection line DCL3-1 and the 3-2-th data connection line DCL3-2.

In the present embodiment, the first and second intermediate bridge pattern layers IBP1 and IBP2 may each have a relatively large first width W1. Therefore, as described above, the risk of formation of unintended conductive portions SD_E or the like around the first and second intermediate bridge pattern layers IBP1 and IBP2 may be reduced, and the risk of degradation in display quality may be reduced.

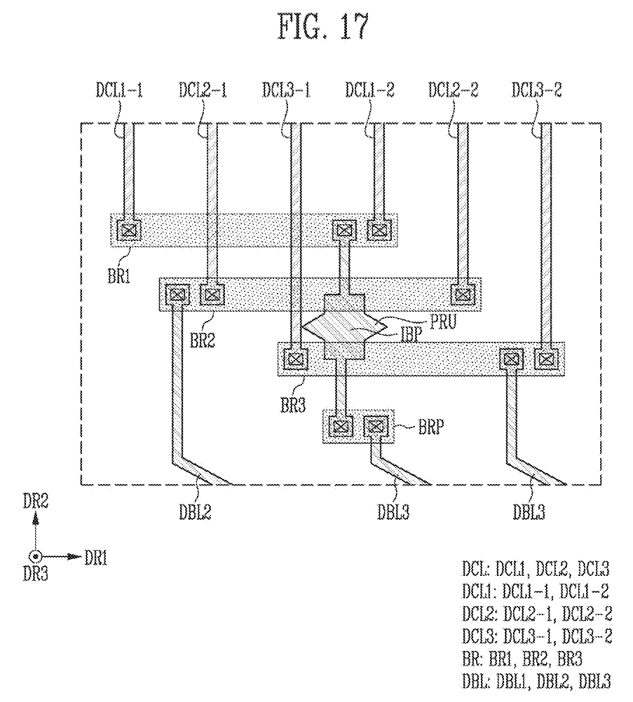

The display device DD including the demultiplexer DUX and lines electrically connected thereto in accordance with an embodiment of the present invention will be described with reference to FIG. 17.

FIG. 17 is a schematic plan view illustrating an area between the demultiplexer DUX and the driving circuit part in accordance with an embodiment of the present invention.

The display device DD in accordance with the present embodiment is different from the display device DD in accordance with the aforementioned embodiment in that the intermediate bridge pattern layer IBP includes a protrusion PRU protruding in a certain direction (e.g., the first direction DR1).

The protrusion PRU may protrude from one or more side surfaces of the intermediate bridge pattern layer IBP. The protrusion PRU may include a first protrusion formed on a first side of the intermediate bridge pattern layer IBP, and a second protrusion formed on a second side of the intermediate bridge pattern layer IBP. The protrusion PRU may include a plurality of protrusions, and the number of protrusions PRU is not limited to a specific number.

The protrusion PRU may be disposed between the second and third bridge layers BR2 and BR3. The protrusion PRU may protrude from side surfaces of the intermediate bridge pattern layer IBP that are between the second and third bridge layers BR2 and BR3.

The present embodiment also allows the intermediate bridge pattern layer IBP to have a relatively large width. Therefore, as described above, the risk of formation of unintended conductive portions SD_E or the like around the intermediate bridge pattern layer IBP may be reduced, and the risk of degradation in display quality may be reduced.

In addition, the protrusion PRU may have a relatively small width due to a protruding shape thereof. For example, the protrusion PRU may have a triangular shape. Accordingly, a step difference may be formed around the protrusion PRU. Even if residual conductive portions SD_E are formed around the second and third bridge layers BR2 and BR3, the step difference formed by the protrusion PRU may increase a path for the residual conductive protrusions SD_E to contact each other. Hence, the risk of a short circuit between the second and third bridge layers BR2 and BR3 may be preliminarily prevented.

A display device DD according to an embodiment is applicable to various types of electronic devices. In an embodiment, an electronic device includes the above-described display device DD and may further include other modules or devices having additional functions in addition to the display device DD.

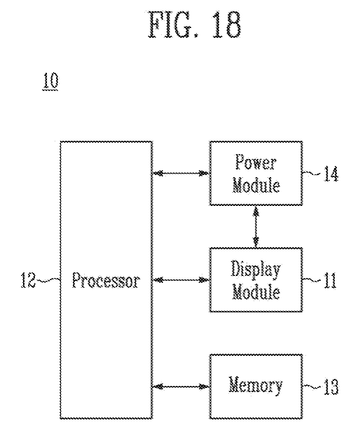

FIG. 18 is a block diagram of an electronic device according to an embodiment. Referring to FIG. 18, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device DD according to embodiments as described above. In addition, in terms of functionality, some of the individual modules included in one module may be included in the display device DD and others may be provided separately from the display device DD. For example, the display module 11 is included in the display device DD, whereas the processor 12, the memory 13, and the power module 14 are not included in the display device DD and are instead provided separately in the electronic device 10.

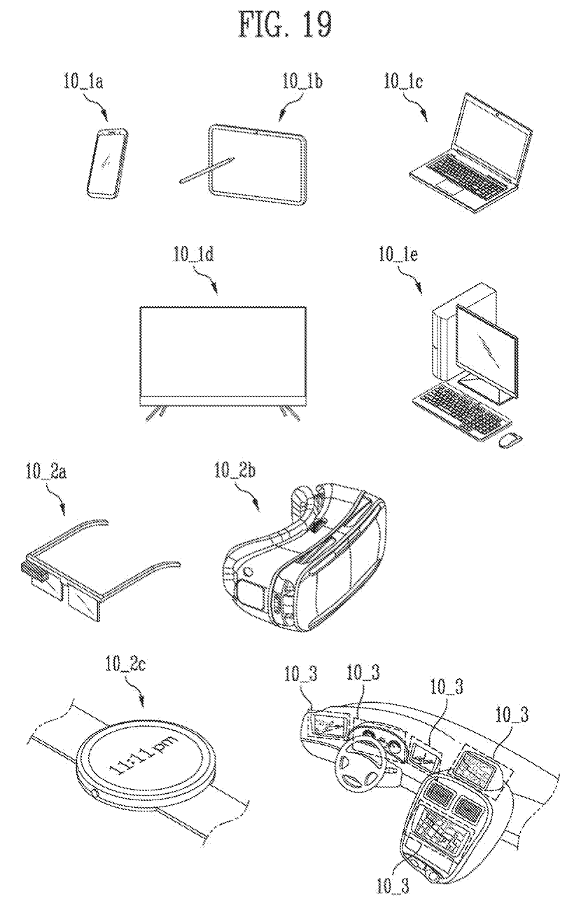

FIG. 19 shows schematic views of various embodiments of an electronic device.

Referring to FIG. 19, various types of electronic devices to which embodiments of a display device DD are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Various embodiments of the present invention may provide a display device in which a structure of lines is suitably patterned in an intended structure and an electronic device comprising the display device.

Various embodiments of the present invention may provide a display device capable of increasing process yield and an electronic device comprising the display device.

Various embodiments of the present invention may provide a display device capable of preventing a risk of an unintended residual conductive structure from being during a fabrication process and an electronic device comprising the display device.

Various embodiments of the present invention may provide a display device capable of reducing a risk of short circuits between lines and an electronic device comprising the display device.

While the present invention has been particularly shown and described with reference to embodiments thereof, it will be apparent to those of ordinary skill in the art that various changes in form and detail may be made thereto without departing from spirit and scope of the present invention.

Therefore, the embodiments disclosed in this specification are only for illustrative purposes rather than limiting the technical spirit of the present invention.

What is claimed is:

1. A display device including a display area and a non-display area, the display device comprising:
a base layer formed across the display area and the non-display area;
pixels disposed on the base layer and in the display area, wherein each of the pixels includes sub-pixels;
a demultiplexer disposed in the non-display area;
a driving circuit part disposed adjacent to the demultiplexer and disposed in the non-display area;
data lines electrically connecting the demultiplexer to the sub-pixels;
a data base line electrically connecting the demultiplexer to the driving circuit part, wherein the data base line includes a first data base line and a second data base line;
a data connection line electrically connecting the demultiplexer to the data base line, wherein the data connection line includes a first data connection line and a second data connection line, wherein the first data connection line is electrically connected to the first data base line and includes a 1-1-th data connection line and a 1-2-th data connection line, and the second data connection line is electrically connected to the second data base line and includes a 2-1-th data connection line and a 2-2-th data connection line;
a bridge layer including a first bridge layer and a second bridge layer, wherein the first bridge layer is electrically connected to the 1-1-th data connection line and the 1-2-th data connection line, and the second bridge layer is electrically connected to the 2-1-th data connection line and the 2-2-th data connection line; and
an intermediate bridge pattern layer electrically connecting the first data base line to the first bridge layer,
wherein the intermediate bridge pattern layer overlaps the second bridge layer, and has a width greater than a width of the first data base line.

2. The display device of claim 1,
wherein the intermediate bridge pattern layer includes a side surface that forms an interfacial angle with respect to a layer on which the intermediate bridge pattern layer is disposed, and
wherein the interfacial angle ranges from about 30° to about 70°.

3. The display device of claim 2, wherein a width of the intermediate bridge pattern layer is about 6 μm or more.

4. The display device of claim 2, wherein a thickness of the intermediate bridge pattern layer ranges from about 3600 Å to about 4200 Å.

5. The display device of claim 4,
wherein the intermediate bridge pattern layer comprises a first conductive layer including titanium (Ti), and a second conductive layer disposed on the first conductive layer and including aluminum (Al),
wherein a thickness of the first conductive layer ranges from about 200 Å to about 400 Å, and
wherein a thickness of the second conductive layer ranges from about 3200 Å to about 3800 Å.

6. The display device of claim 2, further comprising:
a first interlayer conductive layer disposed on the base layer;
a second interlayer conductive layer disposed on the first interlayer conductive layer; and
a transistor conductive layer disposed on the second interlayer conductive layer,
wherein the data connection line is formed from the first interlayer conductive layer,
wherein the data base line and the intermediate bridge pattern layer are formed from the second interlayer conductive layer, and
wherein the bridge layer is formed from the transistor conductive layer.

7. The display device of claim 1,
wherein the pixels comprises a first pixel and a second pixel adjacent to each other in a first direction,
wherein the demultiplexer comprises a first demux transistor and a second demux transistor,
wherein the first pixel is electrically connected to the first demux transistor, and
wherein the second pixel is electrically connected to the second demux transistor.

8. The display device of claim 7, further comprising:
a first select control line electrically connected to a gate electrode of the first demux transistor; and
a second select control line electrically connected to a gate electrode of the second demux transistor,
wherein each of the first select control line and the second select control line extend in the first direction.

9. The display device of claim 7,
wherein the first demux transistor comprises a plurality of first demux transistors,
wherein the second demux transistor comprises a plurality of second demux transistors,
wherein the 1-1-th data connection line is electrically connected to one of the plurality of first demux transistors,
wherein the 2-1-th data connection line is electrically connected to another of the plurality of first demux transistors,
wherein the 1-2-th data connection line is electrically connected to one of the plurality of second demux transistors, and
wherein the 2-2-th data connection line is electrically connected to another of the plurality of second demux transistors.

10. The display device of claim 9, wherein the 1-1-th data connection line, the 1-2-th data connection line, the 2-1-th data connection line, and the 2-2-th data connection line extend in a second direction that is different from the first direction.

11. The display device of claim 10,
wherein the first bridge layer electrically connects the 1-1-th data connection line and the 1-2-th data connection line, which are spaced apart from each other in the first direction, to each other, and
wherein the second bridge layer electrically connects the 2-1-th data connection line and the 2-2-th data connection line, which are spaced apart from each other in the first direction, to each other.

12. The display device of claim 11, wherein the second bridge layer is disposed between the first bridge layer and the first data base line such that the intermediate bridge pattern layer and the second bridge layer overlap each other.

13. The display device of claim 12, wherein at least a portion of the data base line extends in the second direction.

14. The display device of claim 13, further comprising a bridge pattern layer electrically connecting the first data base line and the intermediate bridge pattern layer to each other, and disposed on a layer that is different from which the first data base line and the intermediate bridge pattern layer are disposed on.

15. The display device of claim 10,
wherein the sub-pixels comprises a first sub-pixel, a second sub-pixel, and a third sub-pixel,
wherein the data lines comprise a 1-1-th data line electrically connected to the first sub-pixel of the first pixel, a 2-1-th data line electrically connected to the second sub-pixel of the first pixel, a 3-1-th data line electrically connected to the third sub-pixel of the first pixel, a 1-2-th data line electrically connected to the first sub-pixel of the second pixel, a 2-2-th data line electrically connected to the second sub-pixel of the second pixel, and a 3-2-th data line electrically connected to the third sub-pixel of the second pixel,
wherein the 1-1-th data line, the 2-1-th data line, and the 3-1-th data line are respectively electrically connected to the plurality of first demux transistors, and
wherein the 1-2-th data line, the 2-2-th data line, and the 3-2-th data line are respectively electrically connected to the plurality of second demux transistors.

16. The display device of claim 15,
wherein the data base line comprises a third data base line,
wherein the data connection line comprises a third data connection line including a 3-1-th data connection line and a 3-2-th data connection line, and electrically connected to the third data base line, and
wherein the 3-1-th data connection line extends in the second direction, and overlaps the first bridge layer and the second bridge layer.

17. The display device of claim 16,
wherein the bridge layer comprises a third bridge layer electrically connected to the 3-1-th data connection line and the 3-2-th data connection line, and
wherein the second bridge layer is disposed between the first bridge layer and the third bridge layer.

18. The display device of claim 17, wherein the intermediate bridge pattern layer is disposed across the second bridge layer and the third bridge layer, and overlaps at least a portion of the second bridge layer, and overlaps at least a portion of the third bridge layer.

19. The display device of claim 17,
wherein the intermediate bridge pattern layer comprises a first intermediate bridge pattern layer and a second intermediate bridge pattern layer, wherein the first intermediate bridge pattern layer overlaps the second bridge layer, and the second intermediate bridge pattern layer overlaps the third bridge layer, and
wherein the first intermediate bridge pattern layer and the second intermediate bridge pattern layer are spaced apart from each other.

20. An electronic device, comprising:
a display device; and
a power supply configured to provide power to the display device,
wherein the display device comprises:
a display area;
a non-display area;
a base layer formed across the display area and the non-display area;
pixels disposed on the base layer and in the display area, wherein each of the pixels includes sub-pixels;
a demultiplexer disposed in the non-display area;
a driving circuit part disposed adjacent to the demultiplexer and disposed in the non-display area;
data lines electrically connecting the demultiplexer to the sub-pixels;
a data base line electrically connecting the demultiplexer to the driving circuit part, wherein the data base line includes a first data base line and a second data base line;
a data connection line electrically connecting the demultiplexer to the data base line, wherein the data connection line includes a first data connection line and a second data connection line, wherein the first data connection line is electrically connected to the first data base line and includes a 1-1-th data connection line and a 1-2-th data connection line, and the second data connection line is electrically connected to the second data base line and includes a 2-1-th data connection line and a 2-2-th data connection line;
a bridge layer including a first bridge layer and a second bridge layer, wherein the first bridge layer is electrically connected to the 1-1-th data connection line and the 1-2-th data connection line, and the second bridge layer is electrically connected to the 2-1-th data connection line and the 2-2-th data connection line; and
an intermediate bridge pattern layer electrically connecting the first data base line to the first bridge layer,
wherein the intermediate bridge pattern layer overlaps the second bridge layer, and has a width greater than a width of the first data base line.
